(19) United States
(12) Patent Application Publication
(10) Pub. No.: US 2024/0191341 A1
(43) Pub. Date: Jun. 13, 2024

(54) STABLE GROUND ANODE APERTURE FOR THIN FILM PROCESSING

(71) Applicant: INTEVAC, INC., Santa Clara, CA (US)

(72) Inventors: Samuel D. Harkness, IV, El Cerrito, CA (US); Thomas P. Nolan, Fremont, CA (US); Stephen M. Daly, Los Gatos, CA (US); Jae Ha Choi, Pleasanton, CA (US); Zachary Lyons, Santa Clara, CA (US); Jim Sullivan, Santa Clara, CA (US); Mike Anthony, Santa Clara, CA (US); Todd Morimoto, Santa Clara, CA (US)

(21) Appl. No.: 18/537,523

(22) Filed: Dec. 12, 2023

Related U.S. Application Data
(60) Provisional application No. 63/434,048, filed on Dec. 20, 2022.
(60) Provisional application No. 63/431,999, filed on Dec. 12, 2022.
(60) Provisional application No. 63/431,984, filed on Dec. 12, 2022.
(60) Provisional application No. 63/431,969, filed on Dec. 12, 2022.

(51) Int. Cl. C23C 14/35; C23C 14/50; C23C 14/56

(52) U.S. Cl. CPC C23C 14/352; C23C 14/50; C23C 14/568

(57) ABSTRACT

A plasma chamber for physical vapor deposition, having an anode aperture shield that reduces the field of view to the substrate for deposition particles from the sputtering target. The anode aperture shield limits the deposition particles reaching the substrate to selected maximum angles from the vertical, and rejects particles approaching with a larger angle from the vertical. The node aperture shield is grounded and may be constructed of an upper plate and a lower plate spaced apart from the upper plate, wherein the upper plate may include perforations or may incorporate an electron filter.

### RELATED APPLICATIONS

This application relates to and claims priority benefit from U.S. Provisional Application Ser. No. 63/434,048, filed on Dec. 20, 2022, and from U.S. Provisional Application Ser. No. 63/431,999, filed on Dec. 12, 2022, and from U.S. Provisional Application Ser. No. 63/431,984, filed on Dec. 12, 2022, and from U.S. Provisional Application Ser. No. 63/431,969, filed on Dec. 12, 2022, the disclosures of which are incorporated herein in their entirety.

### BACKGROUND

### 1. Field

This disclosure relates to systems for forming thin-film layers on substrates using plasma enhanced deposition process.

### 2. Related Art

A growing variety of products with optical displays (including cell phones, smart watches, VR goggles, and screens for pads, laptops and automobiles; require protection from damage during use and handling. One solution is to deposit a protective thin film optical overcoat onto the surface simultaneously optimize the optical performance of the display and protect it from scratches, scuffs, and other damage. High quality thin film materials for a multitude of applications can be produced by physical vapor deposition. High throughput of multiple layer thin film stacks from a few nanometers up to several microns thick can be achieved by employing magnetron cathodes in an in-line pass-through deposition system.

Traditional plasma physical vapor deposition (PVD) chambers decompose precursor gases to thereby ignite and maintain plasma and accelerate particles from the plasma towards a target having a layer of material to be deposited as a desired thin film on a substrate. However, a bi-product of the plasma process includes electrically insulating species, that can cling to various parts of the chamber and form an insulation layer. As such electrically insulating film accumulates on ground surfaces within the process chamber, the anode in the plasma circuit diminishes in viability. As the film accumulates and the anode is coated with insulation, the plasma becomes less stable and predictable, and leads to some or all of the following: high incidence of arcing, poor film uniformity, and decreased deposition rate. The arcing rate corresponds directly to the amount of particulation that degrades the thin film quality on the substrate and the overall usefulness of the deposition process.

A typical use of the PVD chamber is to convert a material from the target's stoichiometry to a film comprising an adjusted oxidation state (compared to the original material). Such films generally become dielectric and often present opportunities in the fields of optics, tribology and diffusion to name a few. The most common practice involves introduction of reactive gases (e.g., O, N, H, etc.) during processing that ultimately form the desired bonding and resultant stoichiometry in the film, e.g., SiAlON. This process will often produce an excessive amount of electrons that may cause deleterious plasma damage and heating effects and thereby inhibit film quality. One remedy utilizes an engineered anode to collect the excessive flux and thereby remove it from possible film interaction. However, the adsorbate typically insulates all surfaces on the interior of the chamber and the anode is no exception. Therefore, the plasma tends to become unstable as the anode “disappears”, i.e., it's electrical potential with respect to the plasma is insulated by oxidation material build-up so that from the perspective of charged particles within the plasma, it doesn't exist.

An in-line pass-through PVD chamber has a transport direction or axis along the travel path of the substrates, and a perpendicular transverse direction or axis along a direction orthogonal to the substrate travel path. Material sputtered from the target will deposit onto the various parts of the substrate travel plane at a multitude of different angles and particle/adatom energies that depend on the geometry of the cathodes and chamber, as well as process parameters including the gas species and pressures, and the flux paths of the magnetic field emanating from the magbar. Further, the properties of deposited material depend on many parameters such as the deposition angle with respect to the target surface, the central axis of the magnetron magnetic confinement, hereinafter clocking of the magbar, the path length traversed in the plasma, the path length traversed between the plasma and the substrate, and the effective carrier gas pressure and scattering cross-sections within the deposition chamber and inside of the plasma. The result is that the adatom energy of sputter material and correspondingly the film properties of the sputtered thin film including hardness, density, stress, refractive index and optical absorption, can vary significantly depending on the position of the substrate in the chamber during deposition, the geometry of the sputter chamber and the process settings. It is thus desired to control these factors to tailor optimal properties of a completed pass-through film.

Cathode design for sputtering system has been previously disclosed, which provides enhanced plasma confinement. The reader is directed to, e.g., U.S. Pat. No. 11,456,162, Harkness IV et al., for example of a cathode design. However, in order to provide continuous ground path in a plasma chamber, it would be beneficial to design an anode structure that prevents accumulation of insulation particles thereupon.

### SUMMARY

The following summary of the invention is included in order to provide a basic understanding of some aspects and features of the invention. This summary is not an extensive overview of the invention, and as such it is not intended to particularly identify key or critical elements of the invention, or to delineate the scope of the invention. Its sole purpose is to present some concepts of the invention in a simplified form as a prelude to the more detailed description that is presented below.

Disclosed embodiments provide a chamber structure having shielding that limits the range of angles and energies of species deposited on the substrate. Aspects disclosed include ability to limit deposition of species approaching the substrate at a shallow angle and permit deposition of species approaching the target at a steep angle, including perpendicular to the surface of the substrate.

Aspects of the disclosed shielding include forming a window with the shielding in order to reduce the line of sight area available for deposition onto the substrate, such that the species can be deposited on the substrate only during such time as the substrate is within the window. The shielding is provided on all four sides of a rectangular chamber, at a level just above the entry and exit opening for the substrate carrier. In embodiments, the shielding covers specified areas in the sputter region to block low energy deposition onto substrates, incorporates sufficient thermal conductivity to keep parts cool during extended use, and may also include features for particle mitigation for extended operation.

Disclosed embodiments also provide an anode design that preserves conductive ground surfaces by physically shadowing in such a manner as to inhibit coating species from accumulating, while still remaining available to impacting plasma electrons. According to embodiments, an anode design is disclosed in which attraction of charged species to the uncoated regions is avoided by the incorporation of magnetic field lines that thereby re-direct species off linear trajectories. The magnetic lines further filter electrons from coating material species. This phenomenon may be limited by the spatial area remaining still conductive after coating action. Furthermore, as anode current focuses into these narrow spaces, the amount of resultant Joule heating jeopardizes process stability. If the magnet structure used to generate the anode-going fields increases in temperature, there may be field loss due to the Curie Effect.

Aspects of this disclosure include an anode for a plasma chamber, having an anode block having a front surface to face a plasma and a rear surface to face away from the plasma; a magnet positioned within the anode block and generating magnetic field lines extending outwardly from the front surface of the anode block; and an electron filter bar spaced apart and extending over the front surface of the anode block and intercepting at least part of the magnetic field lines.

Aspect of the disclosure further include an anode for a plasma chamber, the anode incorporating an electron filter having exposed surface facing the plasma region within the plasma chamber and a hidden surface facing away from the plasma region, the electron filter generating a mirroring effect to deflect electrons from the plasma onto the hidden surface. The electron filter preferably maintains magnetic mirror ratio (r=B(max)/B(min), where B is the magnetic field intensity) greater than 10, and more preferably greater than 100. The electron filter may generate the mirroring effect by incorporating a magnet having strength greater than 30 MGOe.

Disclosed embodiments provide an anode for a plasma chamber, comprising an anode block having a front surface facing plasma within the plasma chamber and a back surface facing away from the plasma, the anode block having a cavity open to the back surface; a magnet positioned within the cavity, the magnet being smaller than the cavity such that the magnet does not physically contact any part of the anode block; and at least one filter bar having a free end positioned over and spaced from the front surface, the filter bar having electrical contact to ground potential.

In a related aspect, disclosed embodiments provide a plasma processing chamber comprising: a vacuum enclosure; a cathode having a target of sputtering material mounted thereupon, the cathode positioned within the vacuum enclosure; a gas injector; at least one anode, the anode having an anode block and a magnet positioned within the anode block, the magnet generating magnetic field lines leading from the anode block to the cathode, the anode further comprising a filter bar coupled to ground potential and positioned to intercept part of the magnetic field lines.

Disclosed aspects also provide a plasma processing chamber comprising: a vacuum enclosure; two cathodes positioned within the vacuum enclosure, each cathode having a rotating cylindrical target with coating of sputtering material and a magnetron positioned within the cylindrical target; a gas injector positioned on a ceiling of the vacuum enclosure between the two cathodes; at least one anode attached to sidewall of the vacuum enclosure, the anode having an anode block and a magnet positioned within the anode block, the magnet generating magnetic field lines leading from the anode block to the cathode, the anode further comprising a filter bar forming a peninsular extension attached to the anode block at its isthmus and defining a hollow area between the anode block and the filter bar.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements and are not drawn to scale.

FIG. 1 schematically illustrates a cross-section of a plasma chamber according to disclosed embodiment, while FIG. 1A schematically illustrates parts of the interior of the chamber of FIG. 1 and FIG. 1B illustrates a cross-section of an anode incorporated within a gas injector, according to disclosed embodiment;

FIG. 2 schematically illustrates a cross-section of the structure and function of electron filter according to disclosed embodiment;

FIG. 3 schematically illustrates a cross-section of the structure and function of electron filter according to disclosed embodiment;

FIG. 4 schematically illustrates a cross-section of a plasma chamber according to disclosed embodiment.

### DETAILED DESCRIPTION

Embodiments of the inventive anode aperture shield arrangements will now be described with reference to the drawings. Different embodiments may be used for processing different substrates or to achieve different benefits, such as throughput, film uniformity, target utilization, etc. Depending on the outcome sought to be achieved, different features disclosed herein may be utilized partially or to their fullest, alone or in combination with other features, balancing advantages with requirements and constraints. Therefore, certain features and benefits will be highlighted with reference to different embodiments, but are not limited to the disclosed embodiments, and the features may be incorporated in other embodiments or with other combinations.

Embodiments disclosed herein may be implemented in any plasma-based processing chamber, and are especially suitable for plasma enhanced physical vapor deposition (PVD or sputtering). The embodiments are beneficial for chambers wherein species from the sputtering target land on the substrates at different energies and angle of approach, such that the resulting film may potentially not be uniform. Also, the embodiments are beneficial in chambers wherein an anode forms a pathway for electrons, acting as a ground electrode. When such anodes are coated with the insulative material, the process is degraded due to the disruption of the path to ground. Disclosed embodiments avoid such degradation by, among others, limiting the line of sight available for deposition and controlled removal of electrons from the plasma.

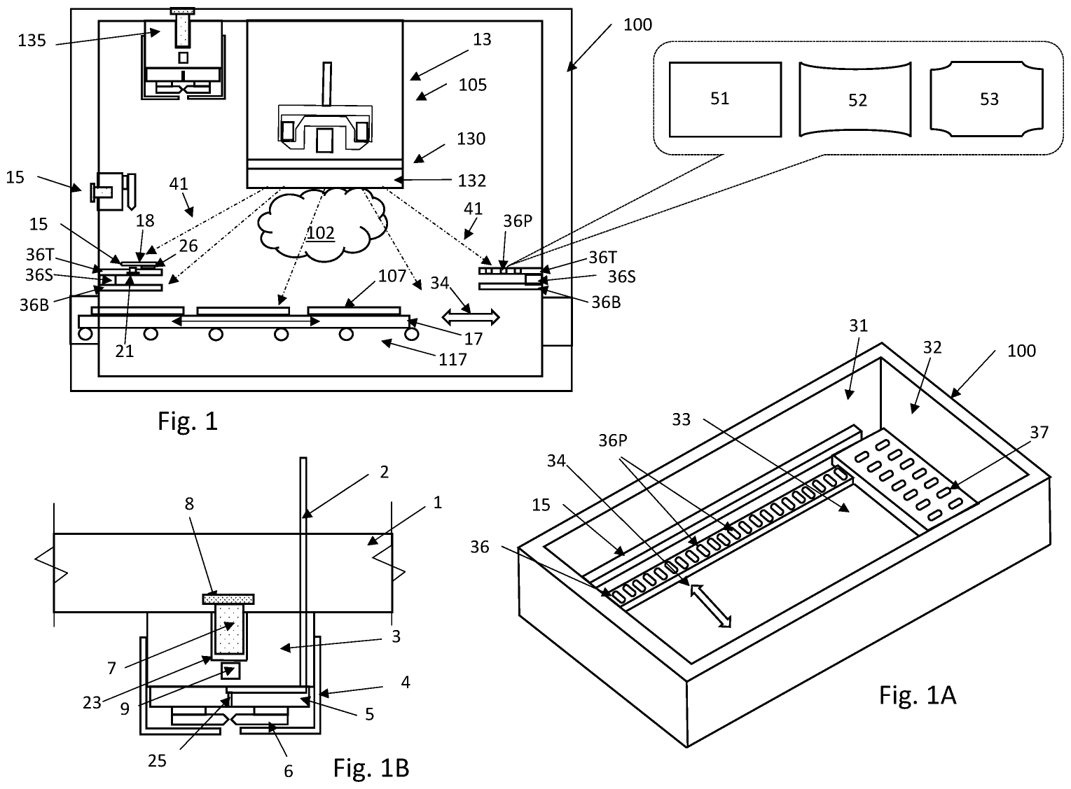

FIG. 1 schematically illustrates a cross-section of a plasma chamber constructed for vacuum processing in the form of physical vapor deposition, having anode aperture shield according to disclosed embodiments. In this embodiment, a sputtering target 130 is mounted onto the ceiling and situated within the vacuum chamber 100, but other sputtering targets may be utilized, e.g., rotating or stationary and attached to the ceiling or sidewall. Also, generally vacuum chamber 100 may be circular, rectangular, square, etc., while for simplicity the disclosed embodiments illustrate rectangular vacuum chamber 100. A magnetron 105 is positioned behind target 130 and ignites and maintains plasma 102 over a front surface of the target 130, such that deposition material 132 of target 130 is bombarded by species from the plasma 102. Particles from deposition material 132 of the target 130 are then sputtered off the target and land on the substrates 107 to form a coating. Here, as an example, the substates travel on a carrier 17, which rides on wheels or transport tracks 117, but the substrate may be stationary or in motion, e.g., on a conveyor, during the sputtering process.

The particles sputtered from deposition material 132 may travel at different angles as they approach substrates 107, as shown by the dash-dot arrows. Film formed on the substrates from particles landing at different approach angle have different optical and physical characteristics. Therefore, in disclosed embodiments an aperture is formed using grounded anodes, that limits the line of sight to substrates available to particles sputtered towards the substrates. The aperture and its different variations will be described below with reference to FIGS. 1 and 1A.

FIG. 1A illustrates a schematic open-top view of the geometry of a pass-through deposition chamber 100 including one embodiment of a ground anode aperture. Chamber 100 includes transverse chamber walls 31 along a transverse axis, transport chamber walls 32 along a transport axis 34, wherein a transport carrier 17 shown traversing the chamber 100 along a transport axis 34 (FIG. 1). The ground anode aperture is formed by two transverse aperture shields 36, each attached to one transverse chamber wall 31, and two transport aperture shields 37, each attached to one transport chamber wall 32. The transverse and transport shields traversing all four walls together comprise an aperture shield that defines aperture 33, which limits line of sight to the substrates from the target, and is roughly rectangular in the embodiment illustrated in FIG. 1A. This aperture shield blocks shallow angle, low energy plasma deposition that produces unwanted low density deposition around the edges of the chamber, as shown by the dash-dot arrows illustrated in FIG. 1. The shallow angle deposition path 41, e.g., larger than 30°, 45° or 60° from the vertical to the substrate, is blocked from depositing film onto carrier 17 by transverse anode shield, allowing only normal and steep angle deposition, thereby increasing the film density and uniformity of a film deposited on substrates 107 crossing the location indicated by the arrow 33 as it passes through the chamber 100.

A previously discussed, the average adatom energy and corresponding film density and other properties may not be uniform across the carrier along the transverse axis. In some embodiments, lateral nonuniformity may be compensated by designing a non-rectangular aperture shield as illustrated in the callout of FIG. 1. Rectangular aperture 51 provides a constant transport path length of enabled deposition across the transverse axis of the carrier. Convex aperture 52 provides an increasingly longer transport path length of enabled deposition across the transverse axis of the carrier. Such an aperture allows less high angle sputter along the transport direction at the center of the transverse axis, that can compensate for the increased high angle sputter owing to receiving more high angle lateral sputter from both sides along the transverse axis. Edge notched aperture 53 is an appropriate design to compensate fast edge deposition along an erosion groove that commonly forms at each end of a cathode for pass-by deposition owing to magnetic flux closure required at each end.

Referring back to FIG. 1, the shields, especially the two transverse aperture shields 36 may be constructed in various designs, two of which are shown in FIG. 1. In each of these designs, the aperture shield is constructed out of a top plate 36T, a bottom plate 36B, and a spacer positioned therebetween 36S. In some embodiments the spacer 36S may include a magnet array embedded therein. At least one of the top plate 36T and bottom plate 36B is conductive and coupled to ground, e.g., by being mounted onto the grounded sidewall of chamber 100. The aperture plates may be fabricated out of Al, Cu or Fe-based materials, e.g., stainless steel. In embodiments the top plate 36T includes perforations 36P.

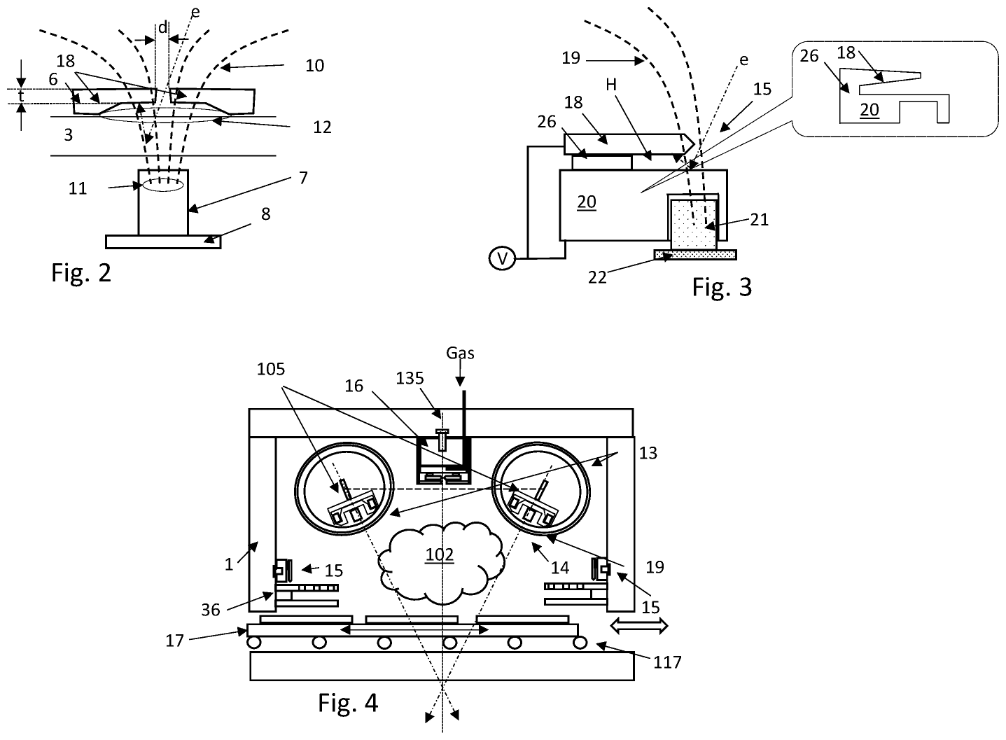

According to another embodiment the top plate 36T of the transverse shield 36 incorporates a grounding anode 15. The structure and function of the anode 15 will be described more fully below with reference to FIGS. 2 and 3.

In operation, plasma is ignited and maintained by injecting precursor gas from injector assembly 135, which in this example also acts as anode, as will be explained with reference to FIG. 2. The flux is generated under classical magnetron dynamics wherein the magnetically confined region defined by the magnetrons 105 enable efficient ionization of gas species such as Ar, Kr, Xe, Ne, He, etc., which subsequently become accelerated toward the cathode held at potential (e.g., −400 V or larger). The impact of these accelerated species imparts sufficient energy to dislodge previously bonded material 132 of the target 130 into the vacuum space where they then become available for deposition on the substrates 107. The targets 130 are made of material 132 that ultimately deposit on the intended substrates 107 with identical stoichiometry. Conversely, the injector assembly 135 may additionally injects reactive gas, such oxygen and/or nitrogen, which would react with the sputtered species, so that the layer formed on the substrates 107 incorporates reacted species.

FIG. 1B is a schematic showing optional features comprising the novel approach to a centralized anode incorporated within the gas injection assembly 135. It should be noted that while in FIG. 1 the gas injection assembly 135 is shown on one sidewall of the chamber, it may actually be placed anywhere that is appropriate for gas injection, e.g., on the ceiling between two cathodes, as shown in FIG. 4. Also, when deployed between two cylindrical rotating targets as shown in FIG. 4, the elements of the centralized anode of FIG. 1A (e.g., anode block 3, magnet array 7, keeper plate 8, gas distribution plate 5, and filters 6) may extend to the length of the cylindrical target (i.e., into the paper as shown in FIG. 1B).

As shown in FIG. 1B, an anode block 3 is affixed to the chamber wall or ceiling 1. The anode block 3 is most appropriately metallic, e.g., aluminum or copper, or otherwise conductive material (both electrical and thermal conductivity). A magnet 7 is mounted on a keeper plate 8, which also affixes directly to the chamber wall 3 and extends into a cavity 23 within anode block 3, such that when at vacuum, there is no connective material making lateral electrical or thermal connection from the magnet 7 directly to the anode block 3. This design criteria is beneficial to inhibiting current flow directly through the magnet structure and preserves thermal stability of the magnet.

Cooling channels 9 are cut into the anode block 3 to allow coolant flow therein to control the temperature of the anode block 3. Additionally, gas delivery line 2 passes through the anode block and provides gas to at least one gas injection orifice 25. The one or more gas injection orifices are provided on a gas distribution plate 5 (also conductive material) that is attached to the top of the anode block 3 and is connected to the gas delivery line 2 to facilitate gas orifice 25 delivery of prescribed gas species to the vacuum environment. Drilled orifices of gas injector 25 are less than 2 mm and more preferably below 1.6 mm in diameter. Such specifications inhibit plasma formation within the plate 5 regardless of the possible electrical potential (as per Paschen's Law). Consequently, less secondary electron generation and consequently lower plasma density forms in the region surrounding the orifice. Also, the at least one orifice is collinear with the highest density of magnet field lines from the magnet 7.

FIG. 2 demonstrates the spatial relationship for the structure of electron filter 6. This filter 6 consists of two filter bars 18 facing each other with a gap therebetween, marked as d. The filter 6 features dimensions that promote the separation of electrons following magnetic field lines from adsorbate particles following line-of-sight trajectories. Specifically, the overall thickness t of the free-standing end of the filter bar is larger, and preferably twice as thick as the distance d separating nearest edge of the mirroring filter bars 18 across the centerline of the anode structure. In embodiments the thickness t is greater than 3 millimeters and may even be greater than 5 millimeters. This collimation optimizes the competing effects of filtering and total capture of electrons. Also, the free-standing end of the filter bar is beneficially thinner than the opposite end that is attached to the anode block, thus defining a hollow area between the anode block and the filter bars.

FIG. 2 illustrates the electron mirroring benefit to ground capture. Magnetic field lines (dashed curves) 10 connect cathode arrays to the center of the anode. A region 11 (dotted oval) shows the densification of field lines as they approach the anode magnet 7. The increase in field intensity, B, causes the reflection of inbound electrons e. The likelihood of momentum transfer causes the electron to reverse course at an angle to the incidence, see dash-dot arrow marked e. As such the collection of reflected trajectories forms a loss cone that is wider than the aperture that admitted the electrons into the anode filter structure. This is represented as dotted oval 12 in FIG. 2, within the hollow space defined between the anode block 3 (or the gas distribution plate 5 if used) and the filter bars 6. The loss reflection allows electrons to then impact on fresh conductive interior surfaces of the filter bars 6, that provide ultimately a pathway to ground. In this way, the anode is kept viable regardless of coating action in the body of the chamber. That is, even if the front surface (i.e., plasma facing surface) of filter 6 gets coated with insulative material, the interior surface (i.e., surfaces hidden from the plasma) would remain exposed and therefore viable conductive pathway to ground.

Reverting to FIG. 1B, this set of phenomena reduces the chance for insulating material such as oxides or nitrides to form atop the conductive metal surface of plate 5 or other local structures, such as the electron filter 6. This optimizes the anode structure for durable performance over extended campaign times. To facilitate the rigors of manufacturing, a consumable or sacrificial shield 4 attaches to the outer portion of the anode block 3, where accumulated material clings to further protect the anode from deposition of insulative material.

Another embodiment of an anode 15 is shown positioned on the sidewall of the chamber, peripherally of the cathodes 13 and above the anode aperture or, in some embodiments, attached to the top plate of the anode aperture. The details of such an anode are explained with reference to FIG. 3. A peripheral anode block 20 is attached to the chamber wall 100. In embodiments wherein the anode 15 is incorporated into the top plate 36T of the aperture, the top plate may function as the anode block 20. Instead of a dual filter structure as shown in FIGS. 1 and 1B, only half such an assembly is required since only one cathode's field lines 19 are connecting to the peripheral anode 15. Filter bar 18 is attached to the anode block 20, set off by spacer 26, to thereby form a peninsula connected to the anode block at its isthmus, and defining hollowed area H between the filter bar 18 and the anode block 20. In this respect, it can be said that the filter bar 18 is cantilevered off of spacer 26. Also, as illustrated in the callout, in any of the disclose embodiments, the anode block 20, spacer 26 and filter bar 18 may be made integrally as a single block having the cavity for the magnet in the rear and the cantilevered filter bar in the front. In any of the disclosed embodiments the free end of the filter bar 18 may be thinner than the attachment end which is attached to the anode block, or the entire filter bar 18 may be tapered towards its free end, as shown in the callout.

Magnet 21 is inserted into cavity in the anode block and is attached to keeper plate 22, wherein no part of the magnet 21 or keeper plate 22 physically contacts the anode block 20, such that a vacuum break is formed between the magnet 21 and keeper plate 22 and the anode block 20. The filter bar 18 is positioned so as to partially cross the magnetic lines emanating from magnet 21, so that some of the magnetic field lines cross the filter bar 18 and some field lines do not cross filter bar 18. Consequently, electrons deflected by the magnetic field would impact the interior surface of the filter bar 18 that faces away from the plasma, and thus remains uncoated by insulating species.

In any of the disclosed embodiments, the anode block may be electrically connected to the chamber body and be at the same potential as the chamber body, e.g., ground potential. Conversely, as exemplified in FIG. 3, the anode block may be insulated from the chamber body and be connected individually to a potential source, or the filter bar may be connected to the potential source. Also, in any of the disclosed embodiments, the magnet has a strength greater than 30 MGOe (mega-gauss-oersted). In any of the disclosed embodiments, the magnetic mirror ratio (r=B(max)/B(min), where B is the magnetic field intensity) is greater than 10 and more preferably greater than 100. In this respect, magnetic mirror refers to the configuration of magnets within the anodes and cathodes to create an area with an increasing density of magnetic field lines at either end of a confinement volume. In the disclosed embodiments the end of interest is at the anode. Particles approaching the ends experience an increasing force that eventually causes them to reverse direction and return to the confinement area. This mirror effect will occur only for particles within a limited range of velocities and angles of approach, while those outside the limits will escape. In the context of the disclosed embodiments, electrons would be deflected to reverse direction and hit the interior side of the electron filter, which is not exposed to insulative coating, thus ensuring clear path to ground for removal of electrons from the plasma.

Reverting to FIG. 1, in embodiments the transverse aperture shield 36 may include an anode 15 with electron filter. As an example, in the left side of the chamber 100 of FIG. 1, anode 15 is incorporated into the aperture shield's top plate 36T; however, both transverse aperture shields may incorporate anode 15. In this particular example, the top plate 36T serves as the anode block and the magnet and keeper plate are mounted onto the top plate. The filter bar 18 and spacer 26 are mounted on the top surface, i.e., the surface facing the plasma 102, of the aperture plate. As noted, generally the aperture shields are attached to the sidewall below the cathode but above an opening through which the substrates are delivered into the chamber, so that the anode 15 may form proper magnetic field lines to the cathode.

Aspect of the disclosed invention include a plasma chamber comprising: a vacuum enclosure having sidewalls and a ceiling, the sidewalls having opening for substrates transport into the vacuum enclosure, a target housed within the vacuum enclosure and having a front surface facing a plasma region within the vacuum enclosure and a rear surface facing away from the plasma region, the front surface being coated with sputtering material; a magnetron positioned behind the rear surface igniting the plasma and confining the plasma to the plasma region; an aperture shield attached to the sidewalls at an elevation below the front surface of the target and above the opening, the aperture shield extending from the sidewalls at an orthogonal angle to the sidewalls, thereby forming an aperture below the plasma region. The aperture shield may comprise a plurality of shield sections, wherein at least one of the shield sections includes an upper shield plate, a bottom shield plate and a spacer positioned between the upper shield plate and the bottom shield plate. The upper shield plate may include perforations. Alternatively, the upper shield plate may include an electron filter, the electron filter may comprise a filter bar and a magnet array positioned within the upper shield plate. Also, the aperture shield may include two transverse aperture shields and two transport aperture shields, wherein the transport aperture shields include perforations. The sidewalls may comprise two transverse chamber walls along a transverse axis and two transport chamber walls along a transport axis, and the aperture shield may include two transverse aperture shields, each attached to one transverse chamber wall, and two transport aperture shields, each attached to one transport chamber wall.

The plasma chamber may further comprise an anode positioned inside the vacuum enclosure and incorporating an electron filter having exposed surface facing the plasma region and a hidden surface facing away from the plasma region, the electron filter generating a mirroring effect to deflect electrons onto the hidden surface. In embodiments, the electron filter maintains magnetic mirror ratio (r=B(max)/B(min), where B is the magnetic field intensity) greater than 10, and more preferably greater than 100. In embodiments, the electron filter incorporates a magnet having strength greater than 30 MGOe. In embodiments, the target is shaped as elongated cylinder and the filter extends to the length of the target, wherein the magnet is formed as an array of magnets extending the length of the target.

FIG. 4 schematically illustrates an embodiment utilizing two rotating cylindrical targets. This embodiment employs dual cylindrical magnetron sputtering arrangement and, more specifically, reactive processing deployed with sufficient symmetry to facilitate pass-by or inline film deposition. In FIG. 4, a cross-sectional schematic drawing shows relative positioning of the two cathodes 13, central gas injection assembly 135 incorporating a central anode 16, two opposing anodes 15, and the aperture shield 36. As illustrated, the two magnetrons 105 within the cylindrical targets are tilted towards one another, such that plasma 102 is maintained between the two cathodes 13. Each of the magnetrons defines an axis of symmetry that passes through its center, represented in FIG. 4 by the dash-dot arrows. The axes of symmetry of the two magnetrons cross each other at a point ahead of the surfaces of the rotating targets. When the two rotating targets are positioned horizontally, i.e., a straight line passing through their axis of rotation is horizontal line (see wide-dash line), the two axes of symmetry cross each other at a crossing point below the horizontal line. Additionally, a straight line connecting the crossing point and the center of gas injection assembly 135 is perpendicular to the horizontal line (see dotted line in FIG. 4). With this orientation, the two cathodes 13 impose a flux of adsorbate material upon a substrate 17 positioned on a tray or carrier, which is either stationary or continuously moving at a prescribed velocity (e.g., 1-30 mm/s). However, the exposure of the substrates to the adsorbate material is limited by the aperture shield 36, so as to limit the range of approach angle of adsorbate particles that can land on the substrate.

In this embodiment, the gas injection assembly 135 incorporating anode 16 is situates on the ceiling of the chamber, at a point midway between the twin cathodes 13, such that the gas injected from the gas injection assembly 135 flows to an area between the targets to maintain plasma between the targets. With this orientation of the rotating targets, central gas injection, and symmetrical anodes, the confinement of plasma has a slope of log(I) vs. log(V) greater than at least 3, and more preferable greater than 4.

In FIG. 4 the gas injection assembly 135 incorporates an anode. In addition, two anodes 15 are positioned on the sidewall opposing each other, such that the magnetic field lines of each anode 15 lead to the corresponding one of cathodes 13. Each of anodes 15 is structured according to embodiments disclosed herein, e.g., see FIG. 3 and its description, wherein the magnetic field lines are partially intercepted by a tapered, free standing edge of filter bar 18. Also, the aperture shield may be grounded and may also serve as anode and may be constructed according to any of the embodiments disclosed herein.

The disclosed embodiments provide a deposition system comprising: a vacuum enclosure having sidewalls, floor and ceiling; two sputtering targets positioned inside the vacuum enclosure and defining a plasma area therebetween, each of the sputtering targets having a front surface coated with sputtering material and a back surface, the front surface facing the plasma area; two magnetrons, each positioned behind the back surface of a corresponding one of the two targets; a gas injector mounted onto the ceiling and positioned centrally between the two targets; substrate transport tracks supporting substrate carriers below the plasma area; and an aperture shield attached to the sidewalls above the transport tracks and defining an aperture between the plasma area and the substrate carrier. The aperture shield may include an upper shield plate and a lower shields plate, wherein the upper shield plate is perforated or alternatively the upper shield plate may incorporate an electron filter. In either configuration, the aperture shield may be grounded and serve as an anode.

In embodiments the deposition system further comprises two peripheral anodes, each mounted onto the sidewall and positioned above the aperture shield and next to a corresponding one of the two targets, each of the peripheral anode comprising an anode block having a cavity, a magnet positioned within the cavity and generating magnetic field lines, and a cantilevered filter bar intercepting at least partially the magnetic field lines. and a central anode mounted onto the ceiling and positioned centrally between the two targets, the central anode having an anode block and a magnet positioned within the anode block; wherein the two targets, the two magnetrons, and the anode confine plasma within the plasma area to have a slope of log(I) vs. log(V) greater than at least 3 or greater than 4.

Also disclosed is a plasma chamber comprising a vacuum enclosure housing a target having a front surface facing a plasma region within the vacuum enclosure and a rear surface facing away from the plasma region, the front surface being coated with sputtering material; a magnetron positioned behind the rear surface igniting the plasma and confining the plasma to the plasma region; an anode position inside the vacuum enclosure and incorporating an electron filter having exposed surface facing the plasma region and a hidden surface facing away from the plasma region, the electron filter generating a mirroring effect to deflect electrons onto the hidden surface; and an anode aperture shield positioned to limit field of view to the substrates from the plasma and/or limit the deposition angle of particles reaching the substrates. In embodiments, the electron filter maintains magnetic mirror ratio (r=B(max)/B(min), where B is the magnetic field intensity) greater than 10, and more preferably greater than 100. In embodiments, the electron filter incorporates a magnet having strength greater than 30 MGOe. In embodiments, the target is shaped as elongated cylinder and the filter extends to the length of the target, wherein the magnet is formed as an array of magnets extending the length of the target.

While the disclosed embodiments are described in specific terms, other embodiments encompassing principles of the invention are also possible. Further, operations may be set forth in a particular order. The order, however, is but one example of the way that operations may be provided. Operations may be rearranged, modified, or eliminated in any particular implementation while still conforming to aspects of the invention.

All directional references (e.g., upper, lower, upward, downward, left, right, leftward, rightward, top, bottom, above, below, etc. are only used for identification purposes to aid the reader's understanding of the embodiments of the present invention, and do not create limitations, particularly as to the position, orientation, or use of the invention unless specifically set forth in the claims. Joinder references (e.g., attached, coupled, connected, and the like) are to be construed broadly and may include intermediate members between a connection of elements and relative movement between elements. As such, joinder references do not necessarily infer that two elements are directly connected and in fixed relation to each other.

In some instances, components are described with reference to “ends” having a particular characteristic and/or being connected to another part. However, those skilled in the art will recognize that the present invention is not limited to components which terminate immediately beyond their points of connection with other parts. Thus, the term “end” should be interpreted broadly, in a manner that includes areas adjacent, rearward, forward of, or otherwise near the terminus of a particular element, link, component, member or the like. It is intended that all matter contained in the above description or shown in the accompanying drawings shall be interpreted as illustrative only and not limiting. Changes in detail or structure may be made without departing from the spirit of the invention as defined in the appended claims.

It must be noted that as used herein and in the appended claims, the singular forms “a”, “an”, and “the” include plural referents unless the context clearly dictates otherwise.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention.

What is claimed is:

1. A physical deposition chamber for forming a film on substrates, comprising:
a vacuum enclosure having sidewall, ceiling and floor;
a substrates carrier positioned over the floor and supporting at least one substrate;
a sputtering cathode positioned within the vacuum enclosure and including a sputtering target and a magnetron, the sputtering target maintaining a plasma that sputters adsorbate particles from the sputtering target at multiple angles towards the at least one substrate;
a gas injector delivering gas to the plasma;
an anode aperture shield attached to the sidewall at a level above the substrate carrier and below the sputtering cathode, the anode aperture shield being grounded and defining an aperture for admittance of adsorbate particles approaching the at least one substrate at angles smaller than a preset angle from vertical to the substrate.

2. The chamber of claim 1, wherein the anode aperture shield comprises a top plate and a bottom plate spaced apart from the top plate, the top plate being perforated.

3. The chamber of claim 1, wherein the anode aperture shield comprises a top plate and a bottom plate spaced apart from the top plate, the top plate having an electron filter attached thereto.

4. The chamber of claim 3, wherein the electron filter comprises a filter bar attached to the top plate and a magnet incorporated within the top plate.

5. The chamber of claim 1, further comprising an anode attached to the sidewall above the anode aperture shield, the anode comprising an anode block includes a magnet inserted within a cavity formed in the anode block, the cavity being larger than the magnet, such that no part of the magnet physically contacts any part of the anode block, and an electron filter bar spaced apart and extending over the anode block and intercepting at least part of magnetic field lines emanating from the magnet.

6. The chamber of claim 5, wherein the magnet strength is greater than 30 mega-gauss-oersted.

7. The chamber of claim 5, wherein the anode block includes cooling channels configured for cooling fluid flow.

8. The chamber of claim 1, wherein the anode aperture shield is made of Al, Cu or Fe-based materials.

9. The chamber of claim 1, wherein the anode aperture shield forms a convex aperture that provides a longer transport path length of enabled deposition across transverse axis of the carrier, orthogonal to direction of travel of the carrier.

10. The chamber of claim 1, wherein the anode aperture shield forms an edge-notched rectangular aperture that provides a longer transport path length of enabled deposition across transverse axis of the carrier, orthogonal to direction of travel of the carrier.

11. A sputtering chamber, comprising:
a vacuum enclosure having sidewalls, floor and ceiling;
two sputtering targets positioned inside the vacuum enclosure and defining a plasma area therebetween, each of the sputtering targets having a front surface coated with sputtering material and a back surface, the front surface facing the plasma area;
two magnetrons, each positioned behind the back surface of a corresponding one of the two targets;
a gas injector mounted onto the ceiling and positioned centrally between the two targets;
substrate transport tracks supporting substrate carriers below the plasma area; and
an aperture shield attached to the sidewalls above the transport tracks and defining an aperture between the plasma area and the substrate carrier.

12. The chamber of claim 11, wherein the transport tracks define a transport direction along travel path of the substrate carriers, and a transverse direction along a direction orthogonal to the travel path of the substrate carriers, and wherein the sidewalls include two transverse chamber walls along the transverse direction and two transport chamber walls along the transport direction, and wherein the aperture shield comprises two transverse aperture shields, each attached to one of the transverse chamber walls and two transport aperture shields, each attached to one of the transport chamber walls.

13. The chamber of claim 12, wherein each of the two transverse aperture shields includes an upper shield plate and a lower shields plate, wherein the upper shield plate is perforated.

14. The chamber of claim 12, wherein the two transport aperture shields are perforated.

15. The chamber of claim 12, wherein each of the two transverse aperture shields includes an upper shield plate and a lower shields plate, wherein the upper shield plate includes an electron filter.

16. The chamber of claim 15, wherein the electron filter comprises a filter bar mounted onto the upper shield plate and a magnet incorporated within the upper shield plate.

17. The chamber of claim 11, further comprising two elongated anodes, each mounted on one of the transverse chamber walls above the transverse aperture shield, and each comprising:
an anode block, the anode block having a cavity formed therein;
a magnet array positioned within the cavity and having no physical contact to the anode block;
a filter bar spaced apart and extending over the front surface of the anode block and intercepting magnetic filed lines emanating from the magnet array.

18. The chamber of claim 11, wherein the aperture shield defines a rectangular opening.

19. The chamber of claim 11, wherein the aperture shield limits range of approach angles of adsorbate particles that can land on the substrates.

20. The chamber of claim 11, wherein the aperture shield provides an increasingly longer transport path length of enabled deposition across the transverse direction.
